(19) United States
(12) Patent Application Publication
(10) Pub. No.: US 2016/0212859 A1
(43) Pub. Date: Jul. 21, 2016

(54) PRINTING ELECTRONIC CIRCUITRY

(71) Applicants: Gil Bellaiche, Herzlyia (IL); Aurel Faibis, Sytrya (IL)

(72) Inventors: Gil Bellaiche, Herzlyia (IL); Aurel Faibis, Sytrya (IL)

(21) Appl. No.: 14/601,285

(22) Filed: Jan. 21, 2015

(51) Int. Cl. H05K 3/10

(52) U.S. Cl. CPC H05K 3/10

(57) ABSTRACT

A method of making a printed circuit board includes providing a substrate; providing a circuit design; determining non-conducting intersections between each of a plurality of conductive traces; forming a first set of conductive traces on the substrate; applying insulation material on the first set of traces at each of the non-conducting intersections; and forming a second set of conductive traces over the first set of traces and insulating material.

### FIELD OF THE INVENTION

The present invention relates to methods and apparatus for printing electronic circuitry by deposition of conductive ink on a substrate.

### BACKGROUND OF THE INVENTION

Most electronic devices comprise a printed circuit board (PCB) bare-board and the electronic components assembled on it. The term “PCB bare-board” refers to the substrates materials, the conductive traces and the coated or uncoated vias.

To prevent unwanted electrical contact between conductors on the board, they are placed on different electrically-insulating layers. Electrical contact between conductors on different layers is achieved with vias drilled through the layers by mechanical means or plasma-processes. These vias are then coated with copper or other electrically conductive materials.

Each insulating layer is a laminate panel, an epoxy resin, and glass-fiber core with copper foil pre-bonded onto each side. The copper foil is covered with a resist layer, a pattern is imaged on the layer and the resist is further developed. At this stage the resist protects certain copper areas. The panel undergoes several chemical processes, such as etching of unprotected copper areas and stripping of the remaining resist.

The technology currently in use in the industry is complicated and expensive, requires:

1. Expensive metallic copper;

2. use of hazardous chemicals which must be disposed of in an environmentally safe manner;

3. extensive equipment which must be operated in a clean room environment; and

4. materials must be manufactured to precise dimensions to ensure registration between layers.

After the layer is prepared, panels are superimposed and laminated. Usually internal-panels are thin and flexible while outer-panels are thicker and less flexible. Electronic components are attached to the outer panels.

U.S. Pat. No. 7,903,428 (Liu et al.) discloses an intra-connection layout with an alterable area disposed between the devices of an array. The alterable area includes an insulation layer, a first group of conductive wires and a second group of conductive wires. The first conductive wires are disposed within the alterable area along a first direction for selectively connecting electrical paths in a first direction between different devices. The second conductive wires are disposed within the alterable area along a second direction for selectively connecting electrical paths in the second direction between different devices. The insulation layer is disposed within the alterable area and between the first conductive wires and second conductive wires. The insulation layer has an opening to allow one of the conductive wires in the first group and one of the conductive wires in the second group to be connected to each other.

U.S. Pat. No. 7,903,428 discloses openings 217 and 218 in the insulation layer which are placed according to the design of the circuit. The second conductive wires are disposed over the insulation layer on previously exposed openings in accordance with a circuit design. In addition, the openings 217, 218 are formed by cutting off parts of the previously disposed insulation layer.

There is a long felt need in the industry to reduce the use of expensive copper, reduce the use of hazardous chemicals and eliminate the need for operating in a clean room.

### SUMMARY OF THE INVENTION

Briefly, according to one aspect of the present invention a method of making a printed circuit board includes providing a substrate; providing a circuit design; determining non-conducting intersections between each of a plurality of conductive traces; forming a first set of conductive traces on the substrate; applying insulation material on the first set of traces at each of the non-conducting intersections; and forming a second set of conductive traces over the first set of traces and insulating material.

The conductive wires are printed with plurality of pads and the insulation areas are printed on the non-conducting intersections before the second conductive wires are printed.

These and other objects, features, and advantages of the present invention will become apparent to those skilled in the art upon a reading of the following detailed description when taken in conjunction with the drawings wherein there is shown and described an illustrative embodiment of the invention.

### BRIEF DESCRIPTION OF THE DRAWINGS

FIG. 1a shows a schematic exploded view of printed conductive traces with the layers separated (prior art);

FIG. 1b shows a schematic of the assembled PCB with the substrate transparent for clarity (prior art);

FIG. 2 shows a schematic representation of printed conductive traces and insulation areas;

FIG. 3 shows a schematic representation of printed conductive traces and insulation paths following the conductive traces;

FIG. 4a shows a schematic representation of printed conductive traces and insulation areas implemented in printing of fixed number of layers;

FIG. 4b shows conductive traces broken into segments in the crossover between two conductive traces;

FIG. 4c shows insulation patches printed over broken segments of conductive traces at crossover between pairs of conductive traces;

FIG. 4d shows conductive traces printed over insulation patches to connect segments of conductive traces; and

FIG. 5 shows a roll to roll printing system.

### DETAILED DESCRIPTION OF THE INVENTION

In the following detailed description, numerous specific details are set forth in order to provide a thorough understanding of the disclosure. However, it will be understood by those skilled in the art that the teachings of the present disclosure may be practiced without these specific details. In other instances, well-known methods, procedures, components and circuits have not been described in detail so as not to obscure the teachings of the present disclosure.

While the present invention is described in connection with one of the embodiments, it will be understood that it is not intended to limit the invention to this embodiment. On the contrary, it is intended to cover alternatives, modifications, and equivalents as covered by the appended claims.

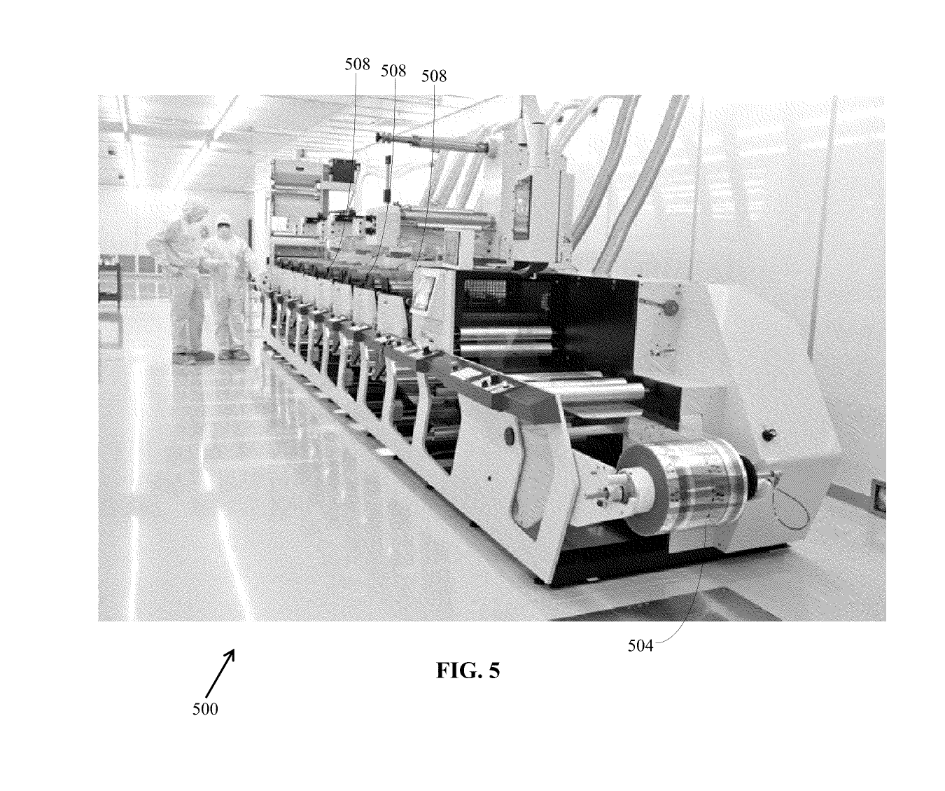

The present invention suggests using roll-to-roll printing devices 500 as is shown in FIG. 5, to print circuit board (PCB) bare-boards. This is accomplished using concepts from the printing industry rather than from the traditional PCB industry. PCB bare-board elements are formed by printing a succession of single layers using a combination of printing ink comprised of conducting and dielectric materials.

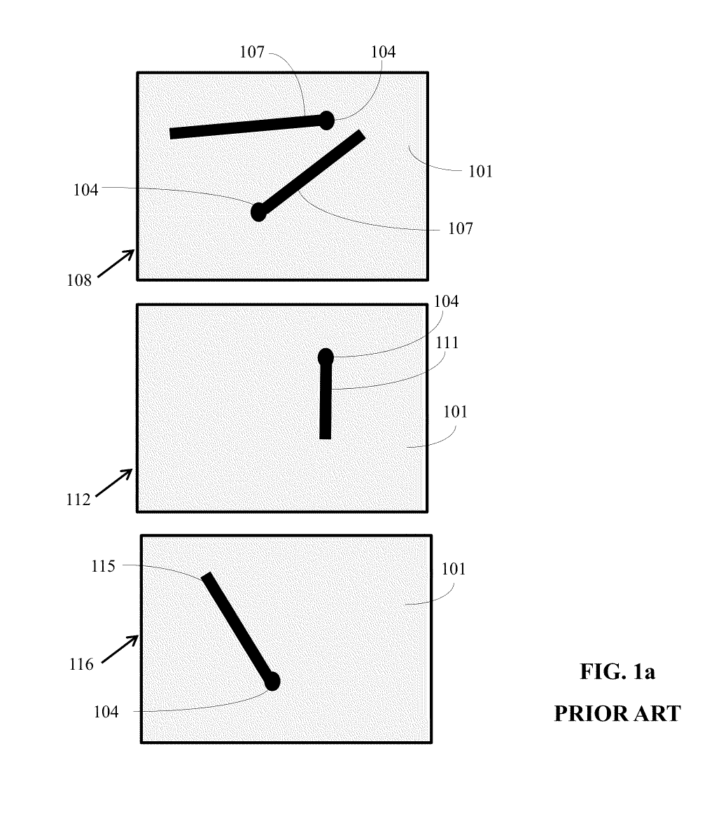

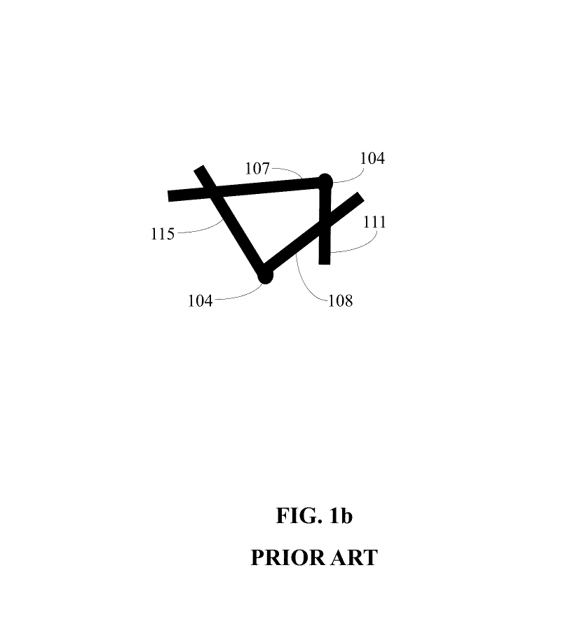

FIG. 1a and FIG. 1b show a schematic layer configuration with conductor traces 107, 111, and 115 printed using traditional PCB manufacturing means. Conducting layers 108, 112, and 116 are isolated from each other by insulating substrates 101. The connection between selected layers is achieved by using vias 104. Vias are vertical holes drilled into the PCB boards, which are filled with conductive material to connect conducting lines from layers 108, 112, and 116 to components, not shown, on the PCB boards.

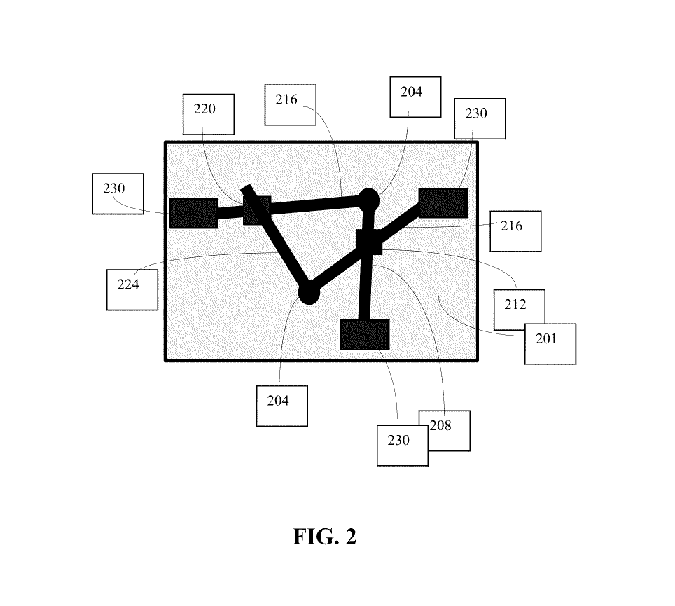

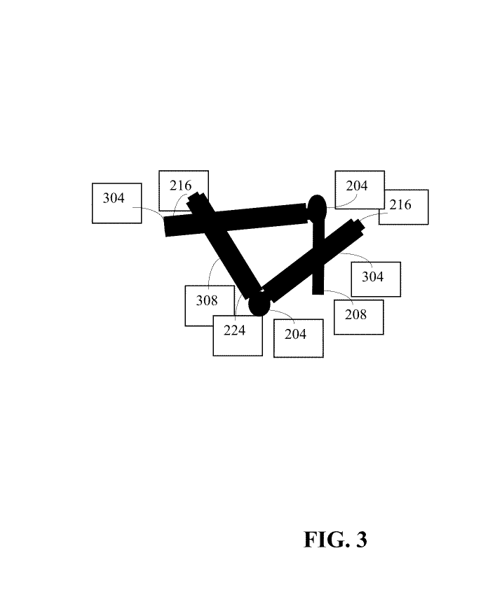

In the present invention, traditional PCB conductors 108, 112 and 116 are replaced by conductive traces 208, 216, and 224 made of conductive ink, as shown in FIG. 2 and FIG. 3, on a single substrate 201. The traditional PCB insulation substrate layers are replaced by printed insulation areas 212, 220, 304, and 308 made of printed, insulating dielectric ink. The traditional PCB vias are replaced by conducting connection dots 204 made of conductive printed material. The present invention thus eliminates using three separate substrates, which must be individually printed, aligned, and assembled; and therefore reduces cost and assembly time. Three different insulation methods, embodiments, are described in more detail below.

In FIG. 2 insulator areas 212 and 220 are formed in the intersection between conductive traces 208, 216 and between 216, 224 respectively. Forming insulation areas such as 212 and 220 rather than full length insulating traces as is shown in FIG. 3, which will be explained in more detail below, carries advantages due to the relatively small quantity of insulating ink needed. The disadvantage is that it requires thorough analysis and calculation to find the cross over locations between each pair of conductors crossing each other.

The “layers” are printed as follows. It should be noted that the order in which the layers are printed may be varied.
‘Layer D’: Conductive dots 204. Intersections created between two or more conductors will not require printing of conductive dots 204 to connect between those conductors.
‘Layer 1 conductive’: conductive trace 208.
‘Layer 2 insulation’: insulation layer 212.
‘Layer 2 conductive’: conductive trace 216.
‘Layer 3 insulation’: insulation layer 220.
‘Layer 3 conductive’: conductive trace 224.
   In an embodiment wherein the substrate is made of dielectric material, the first layer printed on the substrate will be a conductive layer. Alternatively, if certain areas of the substrate are made of conductive material then the first layer printed on the substrate is a dielectric layer.

FIG. 3 shows printing insulators 304 and 308 following the same path as the conductive traces 216 and 224. The only difference between the insulators and the conductive trace is that the insulators are shorter and wider than the conductive traces. In addition, the advantage of following the conductive traces for forming insulation paths does not require complicated geometrical calculation between the layers. The path of the insulation can be calculated directly from the path of the conductive, but requires larger quantities of insulation inks compared to the method demonstrated in FIG. 2.

The geometry of the conductive traces as well the insulation paths or insulation areas, are processed and are separated into distinctive layers. Each layer will include relevant geometry representing only the conductive traces and insulation paths that belong to it. For better understanding of the process refer to FIG. 3. The layers that are printed in one embodiment is as follows:
‘Layer D’: Conductive dots 204. Intersections created between two or more conductors will not require printing of conductive dots 204 to connect between those conductors.
‘Layer 1 conductive’: conductive trace 208.
‘Layer 2 insulation’: insulation layer 304.
‘Layer 2 conductive’: conductive trace 216.
‘Layer 3 insulation’: insulation layer 308.
‘Layer 3 conductive’: conductive trace 224.

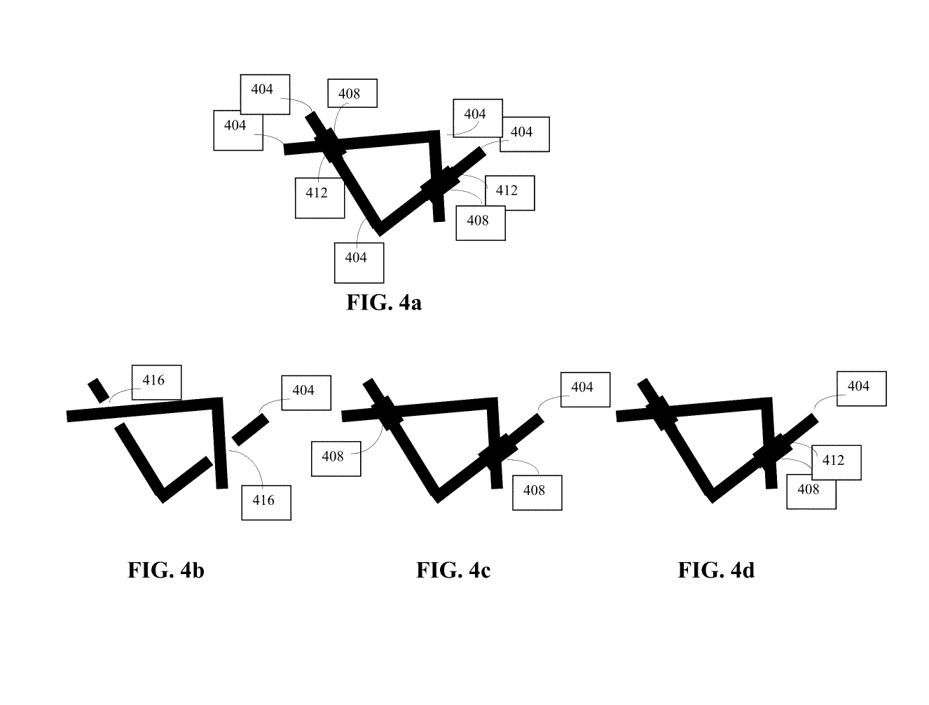

FIG. 4a shows the final results of printing in three steps only. In the first step, all conductive traces 404 of a PCB are printed. Only regions where there is a crossover between two conductive traces with no contact 416 are not printed, as is shown in FIG. 4b. In which case, conductors 404 will be broken into parts or segments. In the second step, the dielectric material 408 is printed over crossover regions 416 as is shown in FIG. 4c. In the third step, the broken conductors are restored by printing a new conductive layer 412 over insulating area 408, as is shown in FIG. 4d.

This embodiment requires also geometrical calculation between the layers. The advantage of this embodiment is that it requires a fixed number of printing layers, in this case just three layers. In this case there is no one-to-one mapping of the layers as in standard PCB printing.

For better understanding the process, reference is made to FIGS. 4a-4d. The layers will be as follows:
‘Layer 1 conductive’: conductive traces 404. All 404 traces are printed, those that are printed with crossover regions broken into few segments, as well as complete traces printed in a single segment.
‘Layer 2 insulation’: print insulation patches 408 for insulating areas of broken conductors 416.
‘Layer 3 conductive’: conductive traces 412 are printed over insulation patches 408 to connect broken segments 416.
   Using the embodiment shown, a fixed number of layers almost every multi-layer PCB can be printed with three layers, two for conductive traces and one for insulation. In cases where shielded signals are required, i.e. surrounded by GND (ground) signals, the number of layers may rise. Additional advantage of printing conductors and insulators is that the paths of the conductors can be shorter.

FIG. 5 illustrates a commercial method of implementing the invention. For each layer, a printing plate 508 will be created. The printing plates 508 are installed on separate rotating drums in a roll-to-roll printing system 500.

Each plate will be coated with relevant ink material during operation of the system 500. Plates representing layers, ‘1 conductive’, ‘2 conductive’ and ‘3 conductive’ will be immersed with conductive ink material, while plates representing layers ‘2 insulation’ and ‘3 insulation’ will be coated with insulation material ink. The final printed circuit will be accumulated on roll 504. In certain cases where inks require longer time to dry, special drying stations (not shown) may be deployed between printing of consecutive printing layers.

Utilizing printing technology in the PCB industry enables printing multiple crossings of conductors or insulators on a single substrate and replaces the plurality of substrates used in the present PCB industry. Printing allows also deposition of the following electronic components 230.
resistors,
capacitors,
inductors,
light-emitting elements,
thermo-chromic elements,
labels
protective and shield layers and more.
   Eventually transistors and batteries could be added to the list.

A list of materials for the various parts of the invention is shown below. The material is illustrative, but is not intended to limit the invention. Polyester PET SH31, ITO (Indium Tin Oxide) may be used for the substrate. FTO Sigma-Aldrich, Polymer Heraeus, carbon nanotubes and grapheme may be used for the transparent conductive film coated on the substrate. Silver screen printing ink C2131014D3 Gwent Group, 125-28 flexographic ink Creative

Materials, 9145 and 5000 Silver conductors, manufactured by Dupont, may be used for the conductive material. D2070209P6 and D2090130P5 Gwent group, Dupont may be used for the insulating material.

While the invention has been described with respect to a limited number of embodiments, these should not be construed as limitations on the scope of the invention, but rather as exemplifications of some of the preferred embodiments. For example, the order of steps for printing conductive traces and insulating areas may be varied. Other possible variations, modifications, and applications are also within the scope of the invention. Accordingly, the scope of the invention should not be limited by what has thus far been described, but by the appended claims and their legal equivalents.

### PARTS LIST

101 insulating substrates
104 conductive vias that pass through the layers
107 conductive traces of layer 2
108 conductive layer 2
111 conductive traces of layer 1
112 conductive layer 1
115 conductive traces of layer 3
116 conductive layer 3
201 insulating substrates
204 conductive connection dots
208 conductive traces of layer 1
212 insulation area
216 conductive traces of layer 2
220 insulation area
224 conductive traces of layer 3
230 electronic component
304 insulation trace between layer 1 and layer 2
308 insulation trace between layer 2 and layer 3
404 entire and broken conductive traces
408 insulation that covers the areas where conductors are broken
412 conductors that restore the broken conductors
416 crossover between two conductive traces with no contact
500 roll-to-roll printing system
504 printed electronics roll
508 printing plates representing separate printed electronics layers

1. A method of making a printed circuit board, comprising:
providing a substrate;
providing a circuit design;
determining non-conducting intersections between each of a plurality of conductive traces;
forming a first set of conductive traces on the substrate;
applying insulation material on the first set of traces at each of the non-conducting intersections; and
forming a second set of conductive traces over the first set of traces and insulating material.

2. The method of claim 1 comprising:
forming a layer of insulation material on the substrate prior to forming the first set of conductive traces if the substrate is at least partially formed with conductive material.

3. The method of claim 1 wherein the insulation material is formed only at areas of the non-conducting intersection between at least two conductive traces.

4. The method of claim 1 wherein the insulation material is formed along a length of each the conductive traces to create an insulation path.

5. The method of claim 4 wherein the insulation path is wider than the conductive trace covered by the insulation path.

6. The method of claim 4 wherein the insulation path is shorter than the conductive trace and both edges of the conductive trace are exposed.

7. The method of claim 1 wherein each of the conductive traces is formed on a different layer.

8. The method of claim 1 wherein at least two of the conductive traces are formed in a single layer.

9. The method of claim 8 wherein the first conductive trace is split into a first conductive segment and a second conductive segment in order to avoid unwanted electrical contact at the non-conducting intersection with the second conductive trace.

10. The method of claim 9 comprising:
applying an insulation segment over the second conductive trace; and
electrically connecting the first conductive segment to the second conductive segment.

11. The method of claim 1 comprising:
connecting electronic components to the conductive traces according to the circuit design.

12. A method of printing an electronic circuit, comprising:
providing a substrate;
providing a circuit design;
determining a location of non-conducting intersections between each of a plurality of conductive traces;
printing a first set of conductive traces on the substrate;
printing insulation material on the first set of traces at each of the non-conducting intersection locations; and
printing a second set of conductive traces over the first set of traces and insulating material.

13. The method of claim 12 comprising:
printing a conductive dot at connecting intersections of conductive traces according to the circuit design.

14. The method of claim 12 comprising:
connecting or printing electronic components to the conductive traces according to the circuit design.

15. A method of printing an electronic circuit, comprising:
providing a substrate;
providing a circuit design;
determining a location of non-conducting intersections between each of a plurality of conductive traces;
printing a first set of conductive traces on the substrate with a gap at the location of non-conducting intersections;
printing a second set of conductive traces over the first set of traces;
printing insulation material at each gap; and
printing conductive traces over the insulation material to connect the first set of traces.

16. The method of claim 15 comprising:
connecting or printing electronic components to the conductive traces according to the circuit design.
